(19) United States
(12) Patent Application Publication
(10) Pub. No.: US 2012/0194993 A1
(43) Pub. Date: Aug. 2, 2012

(54) STAND APPARATUS AND ELECTRONIC APPARATUS SYSTEM THEREFOR

(75) Inventors: Shinji Oguchi, Nagano (JP); Hiroshi Shiobara, Nagano (JP)

(73) Assignee: SONY CORPORATION, Tokyo (JP)

(21) Appl. No.: 13/356,817

(22) Filed: Jan. 24, 2012

(30) Foreign Application Priority Data
Jan. 31, 2011 (JP) P2011-019125

(51) Int. Cl. G06F 1/16; H05K 7/18

(52) U.S. Cl. 361/679.41; 248/346.04

(57) ABSTRACT

A stand apparatus includes a holder, an elastic member, and a displacement operating portion. The holder is configured to hold an electronic apparatus so that the electronic apparatus can be inserted into and pulled out of the holder in a direction orthogonal to a thickness direction, the holder including a pair of wall portions capable of holding the inserted electronic apparatus while pressing the inserted electronic apparatus from both sides in the thickness direction. The elastic member is configured to elastically support the holder. The displacement operating portion is configured to cause the holder to move to a direction opposite to a direction of a repulsion force of the elastic member in response to insertion of the electronic apparatus and to displace at least one of the pair of wall portions to press the electronic apparatus along with the movement.

### BACKGROUND

The present disclosure relates to a stand apparatus that holds an electronic apparatus such as a docking station with the electronic apparatus being in an upright position and to an electronic apparatus system therefor.

The docking station means a function expansion unit for a portable information processing apparatus such as a laptop personal computer. The docking station includes, for example, drives such as an optical drive and a hard disk drive, a wireless communication unit such as a wireless LAN, connection terminals such as a serial port and a parallel port, and a connector for electrical connection with the information processing apparatus. By the docking station adding various functions that are not provided in the portable information processing apparatus, both of portability and functionality of the portable information processing apparatus can be improved. As publicly-known documents regarding the docking station, there are, for example, Japanese Patent Application Laid-open No. HEI 11-024787 and Japanese Patent Application Laid-open No. 2002-108521.

### SUMMARY

Most of the docking stations install a laptop PC with the laptop PC being laid on a top surface thereof or the like. A majority of the docking stations of this type have the same size as that of the laptop PC and a rectangular shape similar to the laptop PC. Therefore, as laptop PCs are decreased in size, the docking stations are also decreased in size. By the way, frequency of use of the electronic apparatus such as a docking station is inevitably low in comparison with the laptop PC itself. Thus, due to the fact that the docking station is small and not used frequently, there may be a case where it is difficult to find the docking station when the user wants to use the docking station. Further, a suitable method of housing the docking station being out of use has not been realized.

In view of the above-mentioned circumstances, there is a need for providing a stand apparatus capable of suitably holding an electronic apparatus by an easy operation and an electronic apparatus system therefor.

According to an embodiment of the present disclosure, there is provided a stand apparatus including: a holder configured to hold an electronic apparatus so that the electronic apparatus can be inserted into and pulled out of the holder in a direction orthogonal to a thickness direction, the holder including a pair of wall portions capable of holding the inserted electronic apparatus while pressing the inserted electronic apparatus from both sides in the thickness direction; an elastic member configured to elastically support the holder; and a displacement operating portion configured to cause the holder to move to a direction opposite to a direction of a repulsion force of the elastic member in response to insertion of the electronic apparatus and to displace at least one of the pair of wall portions to press the electronic apparatus along with the movement.

In this embodiment of the present disclosure, when the electronic apparatus is inserted into the holder, the displacement operating portion causes the holder to move to the direction opposite to the repulsion force of the elastic member due to the load of the electronic apparatus, and along with the movement, the wall portion of the holder is displaced, to thereby bring the electronic apparatus into a restrained state within the holder. When the electronic apparatus is pulled out of the holder, the load of the electronic apparatus is eliminated, and hence the holder moves to the direction of the repulsion force of the elastic member, to thereby cancel the displacement of the wall portion of the holder. As a result, the electronic apparatus is released from the restrained state within the holder is canceled. Thus, according to the stand apparatus, the electronic apparatus can be stably held in an upright position. In addition, it is possible to easily perform the insertion and removal of the electronic apparatus by a single operation of an operation of inserting the electronic apparatus into the holder from the above and an operation of upwardly pulling the electronic apparatus out of the holder.

The holder may include a portion configured to hold a part of a casing of the electronic apparatus, the part including an air hole formed therein, and the portion may include a communication hole capable of communicating to the air hole. In this manner, the communication hole is formed in the holder of the stand apparatus, and hence even if the electronic apparatus is mounted on the stand apparatus immediately after the electronic apparatus is used, it is possible to prevent heat from being trapped in the casing of the electronic apparatus for a long period of time. Thus, it is possible to prevent thermal destruction and the like of function expansion devices in the electronic apparatus.

The stand apparatus according to the embodiment of the present disclosure may further include a positioning portion configured to engage to the casing of the electronic apparatus that is held by the holder, to thereby position the electronic apparatus in a direction orthogonal to an insertion and pull-out direction and the thickness direction of the electronic apparatus. In this manner, the electronic apparatus is positioned and held in the direction orthogonal to the insertion and pull-out direction and the thickness direction of the electronic apparatus, and hence it is possible to ensure positional alignment between the air hole of the electronic apparatus and the communication hole of the holder. At the same time, it is possible to prevent the electronic apparatus from being held by the stand apparatus in an unbalanced manner relative to the stand apparatus.

According to another embodiment of the present disclosure, there is provided an electronic apparatus system for a stand apparatus, including: an electronic apparatus including a device configured to expand a function of an information processing apparatus; and a stand apparatus capable of holding the electronic apparatus, the stand apparatus including a holder configured to hold the electronic apparatus so that the electronic apparatus can be inserted into and pulled out of the holder in a direction orthogonal to a thickness direction, the holder including a pair of wall portions capable of holding the inserted electronic apparatus while pressing the inserted electronic apparatus from both sides in the thickness direction, an elastic member configured to elastically support the holder, and a displacement operating portion configured to cause the holder to move to a direction opposite to a direction of a repulsion force of the elastic member in response to insertion of the electronic apparatus and to displace at least one of the pair of wall portions to press the electronic apparatus along with the movement.

According to the embodiments of the present disclosure, it is possible to suitably hold an electronic apparatus by an easy operation.

### BRIEF DESCRIPTION OF DRAWINGS

FIG. 1 is a perspective view showing a configuration of a docking station system according to a first embodiment of the present disclosure;

FIG. 2 is a perspective view showing a state in which a docking station is mounted on a stand apparatus in the docking station system shown in FIG. 1;

FIG. 3 is a view showing four sides of a docking station;

FIG. 4 is a plan view of the stand apparatus shown in FIG. 1;

FIG. 5 is a side view in a Y-axis direction of the stand apparatus shown in FIG. 1;

FIG. 6 is a side view in an X-axis direction of the stand apparatus shown in FIG. 1;

FIG. 7 is a perspective view showing an inner structure with a part of a housing being removed from the stand apparatus shown in FIG. 1;

FIG. 8 is a cross-sectional view showing a state of a holder portion before the docking station is mounted on the stand apparatus shown in FIG. 1;

FIG. 9 is a cross-sectional view showing a state of the holder portion after the docking station is mounted on the stand apparatus shown in FIG. 1; and

FIG. 10 is a side view illustrating a position for holding the docking station in the X-axis direction in the stand apparatus shown in FIG. 1.

### DETAILED DESCRIPTION OF EMBODIMENTS

Hereinafter, an embodiment of the present disclosure will be described with reference to the drawings.

### First Embodiment

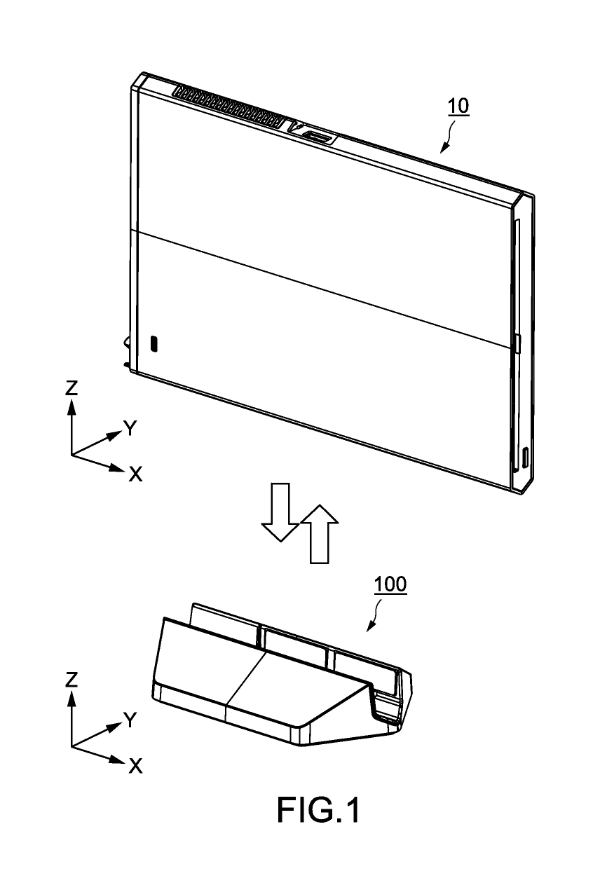

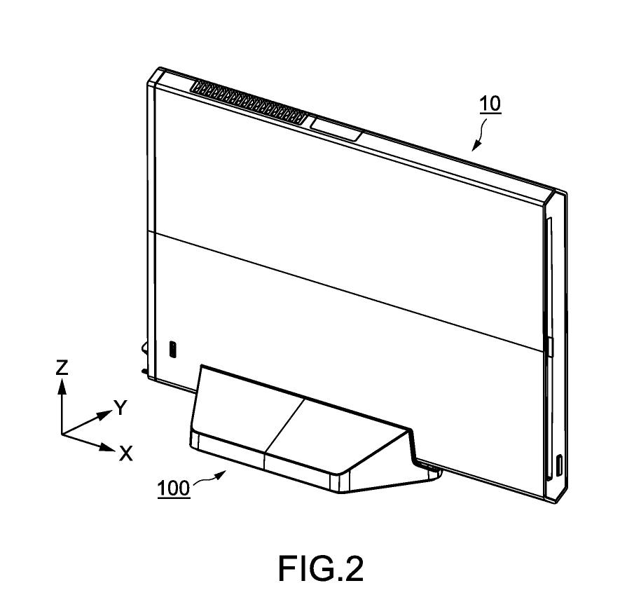

FIG. 1 and FIG. 2 are perspective views each showing a docking station system including a stand apparatus according to a first embodiment of the present disclosure.

The docking station system includes, for example, a docking station 10 and a stand apparatus 100. The docking station 10 serves to expand functions of a portable information processing apparatus (not shown) such as a laptop personal computer. The stand apparatus 100 is capable of holding the docking station 10 so that the docking station 10 can be inserted into and pulled out of the stand apparatus 100. Specifically, the stand apparatus 100 holds the docking station 10 while pressing a casing of the docking station 10 from both sides in a thickness direction (Y-axis direction) thereof with the docking station 10 being in an upright position.

### [Docking Station 10]

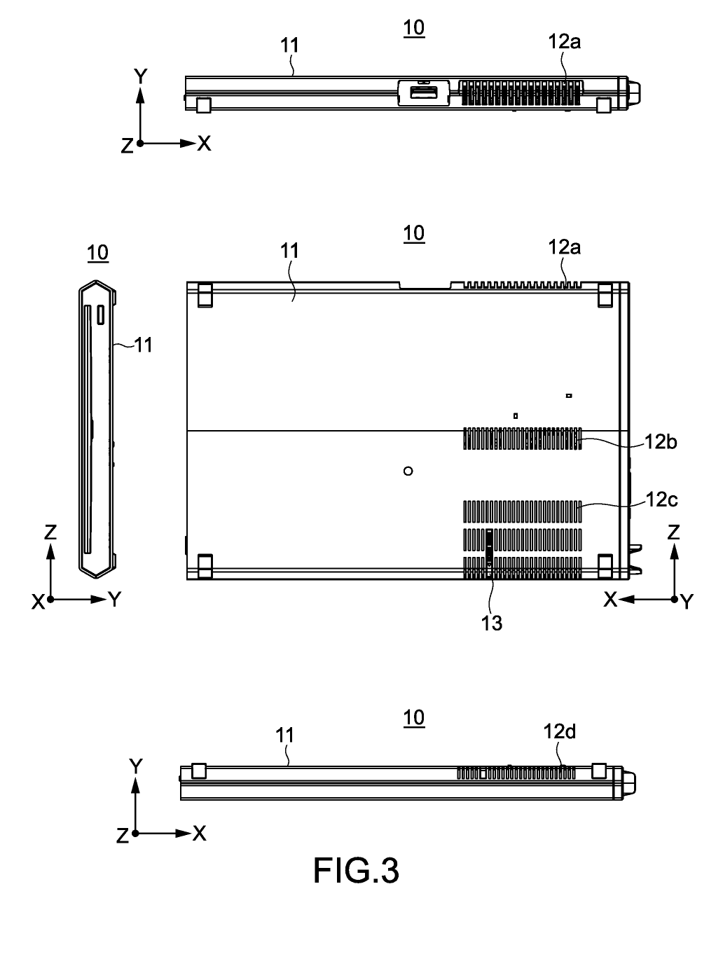

FIG. 3 is a view showing four sides of the docking station 10. It should be noted that an X-Z section of the docking station 10 that is shown in FIG. 3 represents the docking station 10 shown in each of FIG. 1 and FIG. 2 as viewed from the back.

As shown in the drawing, the docking station 10 includes a casing 11 having a substantially rectangular parallelepiped shape as a whole. A direction in which the longest sides of the rectangular parallelepiped casing 11 extend is referred to as an X-axis direction. A direction in which the second longest sides of the rectangular parallelepiped casing 11 extend is referred to as a Z-axis direction. A direction in which the shortest sides of the rectangular parallelepiped casing 11 extend is referred to as a Y-axis direction. The length of the rectangular parallelepiped casing 11 in the Y-axis direction is referred to as the thickness of the casing 11 of the docking station 10. The casing 11 of the docking station 10 houses a group of devices to be used as expansion functions for the portable information processing apparatus such as a laptop personal computer. The group of devices includes, for example, drives such as an optical drive and a hard disk drive, a wireless communication unit such as a wireless LAN (Local Area Network), interfaces such as a serial port and a parallel port, and a GPU (Graphics Processing Unit) for graphic processing. In addition, the casing 11 of the docking station houses necessary components for maintenance of the functions of the group of devices. As one of the necessary components, there is a cooling fan, for example. The casing 11 has a plurality of air holes 12a, 12b, 12c, and 12d at various parts thereof. Those air holes 12a, 12b, 12c, and 12d function to distribute air flow caused by the cooling fan to the inside and outside of the casing 11. Further, one X-Z section of the casing 11 is provided with an engaging portion for positioning the casing 11 when held by the stand apparatus 100.

### [Stand Apparatus 100]

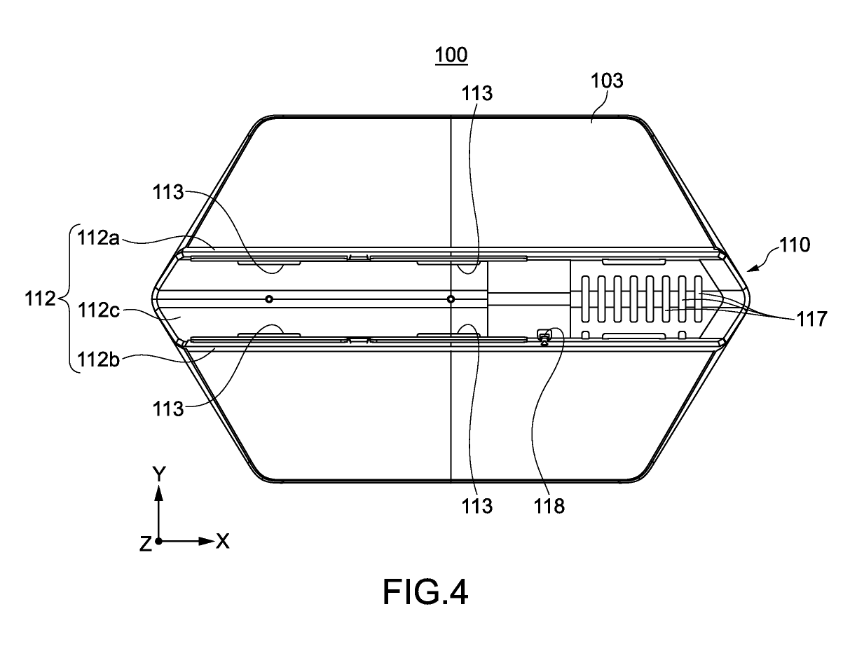

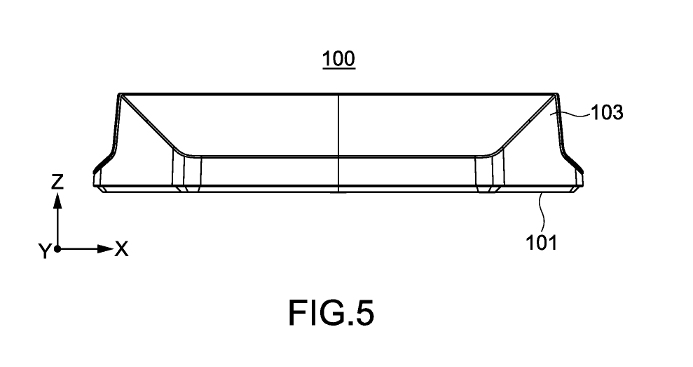

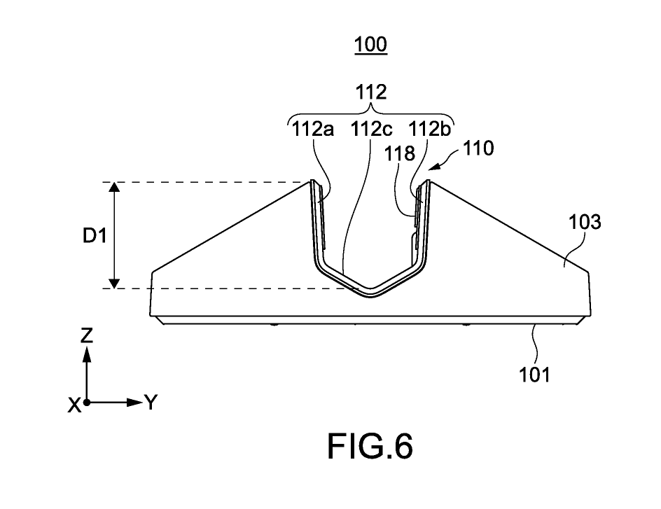

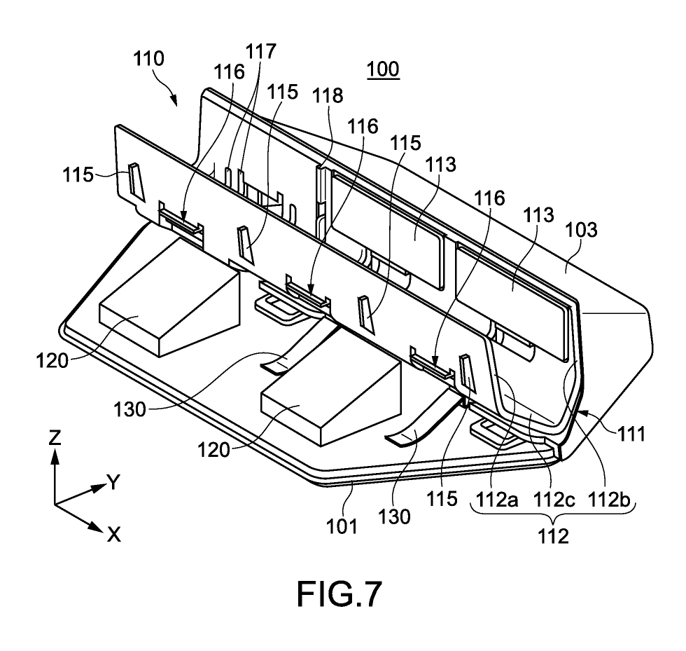

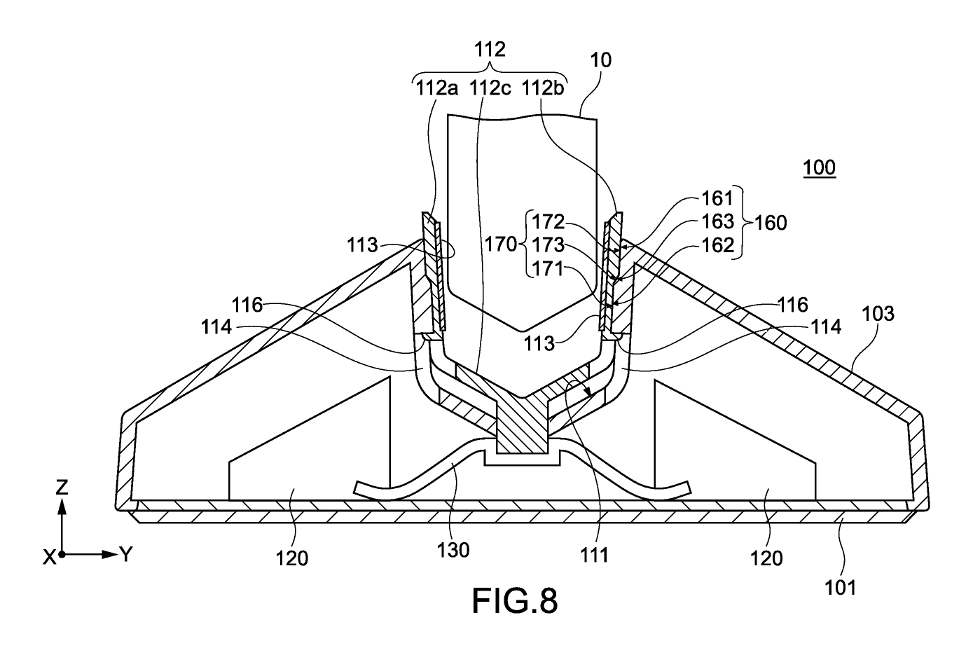

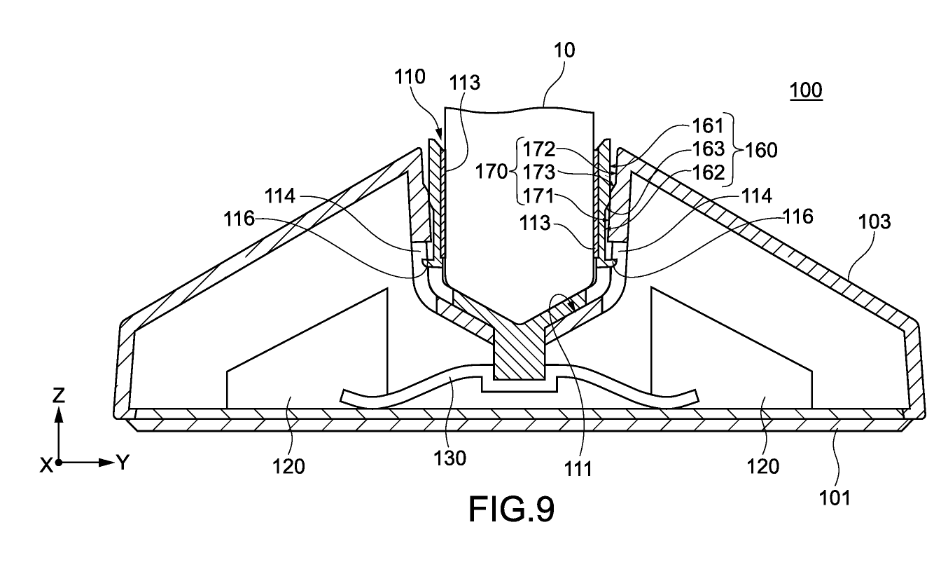

FIG. 4 is a plan view of the stand apparatus 100. FIG. 5 is a side view of the stand apparatus 100 in the Y-axis direction. FIG. 6 is a side view of the stand apparatus 100 in the X-axis direction. FIG. 7 is a perspective view of the stand apparatus 100 with a part of a housing being removed. FIG. 8 and FIG. 9 are cross-sectional views illustrating the details of a holder portion of the stand apparatus 100.

As shown in those drawings, three axis (XYZ-axis) directions of the stand apparatus 100 are defined. Here, the Z-axis direction is a direction of the gravity applied to the stand apparatus 100 when installed.

As shown in those drawings, the stand apparatus 100 includes a bottom plate 101, a housing 103, and a docking station holder portion (hereinafter, referred to as “holder portion”) 110.

In order to stabilize the stand apparatus 100 when placed on a flat surface, the bottom plate 101 is formed of a flat plate. The housing 103 is provided on one surface of the bottom plate 101. The housing 103 is formed to have a hollow structure allowing components such as weights 120 (FIG. 7 to FIG. 9) to be housed between the housing 103 and the surface of the bottom plate 101.

Further, in the center portion of the housing 103 in the Y-axis direction, a groove portion 111 (see FIG. 7 to FIG. 9) having a U-shaped cross-section is formed, the groove portion 111 being to be provided with the holder portion. The groove portion 111 extends from the one end to the other end of the stand apparatus 100 in the X-axis direction. In the groove portion 111 of the housing 103, the holder portion 110 is provided conforming to the inner shape of the groove portion 111.

### [Details of Holder Portion 110]

The holder portion 110 is a portion capable of holding the docking station 10 so that the docking station 10 can be inserted into and pulled out of the holder portion 110 in the Z-axis direction being a direction orthogonal to the thickness direction (Y-axis direction) of the casing 11 of the docking station 10. The holder portion 110 holds the inserted docking station 10 while pressing the inserted docking station from the both sides of the casing 11 in the thickness direction. The holder portion 110 may have such a depth D1 (see FIG. 6) to stably hold the docking station 10 in an upright position and to prevent the operability of the docking station 10 from being lowered when the docking station 10 is inserted and pulled out. For example, the depth D1 of the holder portion 110 may range from about 30 mm to about 50 mm. It should be noted that this value depends on the size of the docking station 10. In this embodiment, employed is the docking station 10 having the following size: for example, the size in the X-axis direction=210 mm, the size in the Z-axis direction=150 mm, and the size (thickness) in the Y-axis direction=15 mm.

Specifically, the holder portion 110 is formed of a holder main body 112. The holder main body 112 includes a U-shaped cross-section conforming to the shape of the cross-section of the groove portion 111 of the housing 103. In the holder main body 112, wall portions opposed to each other are referred to as holder wall portions 112a and 112b, and a portion connecting those two holder wall portions 112a and 112b to each other is referred to as a connection portion 112c. Out of the holder wall portions 112a and 112b, surfaces opposed to each other are provided with cushion portions 113. The cushion portions 113 are provided, for example, by bonding thin-sheet-shaped cushion materials to the surfaces of the holder wall portions 112a and 112b. The cushion portions 113 are portions to be brought into direct contact with surfaces of the casing 11 of the docking station 10. Therefore, the cushion portions 113 are made of soft materials in order to prevent the surfaces of the casing 11 of the docking station 10 from being damaged and further to stably hold the casing 11.

Above the bottom plate 101, the holder main body 112 is elastically supported by elastic members 130 such as leaf springs (see FIG. 7 to FIG. 9). The holder main body 112 is set to be movable within a predetermined range in the Z-axis direction in the groove portion 111 of the housing 103. The range of movement of the holder main body 112 may be, for example, about 10 mm. However, the range of movement of the holder main body 112 may be larger or smaller than this value. In order to allow the holder main body 112 to move in the Z-axis direction, a plurality of guide grooves (not shown) and a plurality of movement-limiting portions 114 (FIG. 8 and FIG. 9) are formed in inner wall surfaces, which are opposed to each other in the Y-axis direction, of the groove portion 111 of the housing 103. On the other hand, outer surfaces of the holder wall portions 112a and 112b opposed to each other of the holder main body 112 are provided with a plurality of guide ribs 115 (see FIG. 7) and a plurality of engaging portions 116 (see FIG. 7 to FIG. 9). The plurality of guide ribs 115 are engaged to the plurality of guide grooves formed in the groove portion 111 of the housing 103. The plurality of engaging portions 116 are engaged to the plurality of movement-limiting portions 114 formed in the groove portion 111 of the housing 103.

More specifically, the movement-limiting portions 114 of the housing 103 are openings formed in the housing 103, and the engaging portions 116 of the holder main body 112 are protrusions to be inserted into those openings. Thus, in the groove portion 111 of the housing 103, the holder main body 112 is movable between a top position when the protrusions serving as the engaging portions 116 are positioned at upper ends in the openings serving as the movement-limiting portions 114 that are formed in the housing 103 as shown in FIG. 8 and a bottom position when the protrusions are positioned at lower ends in the openings of the housing 103 as shown in FIG. 9. Further, upward and downward movement of the holder main body 112 in the groove portion 111 of the housing 103 can be stably performed because the engagement between the guide grooves (not shown) of the housing 103 and the guide ribs 115 of the holder main body 112 limits a moving direction of the holder main body 112.

As described above, above the bottom plate 101, the holder main body 112 is elastically supported by the elastic members 130 such as leaf springs (see FIG. 7 to FIG. 9). The repulsion force of the elastic members 130 is selected satisfying the following conditions.

1. When the holder portion 110 does not hold the docking station 10, the holder main body 112 is raised and placed in the top position.

2. When the holder portion 110 holds the docking station 10 (the weight of the docking station 10 is added), the holder main body 112 descends and is placed in the bottom position.

In addition, in the stand apparatus 100 according to this embodiment, a distance between the holder wall portions 112a and 112b of the holder main body 112 is set to vary along with the movement of the holder main body 112 in the Z-axis direction. Next, a configuration (displacement operating portion) for realizing such an operation of the holder main body 112 will be described.

The holder main body 112 is made of a material having certain viscosity and certain strength, for example, a synthetic resin. Additionally, the holder main body 112 has a U-shaped cross-section, and hence the holder main body 112 elastically deforms relatively easily in a direction in which the distance between the holder wall portions 112a and 112b opposed to each other varies. The outer surfaces of the pair of holder wall portions 112a and 112b of the holder main body 112 and the inner wall surfaces of the groove portion 111 of the housing 103, which are opposed to the outer surfaces, are provided with step portions 160 and 170. The step portions 160 and 170 serve to vary the distance between the holder wall portions 112a and 112b by interfering with each other in response to the upward and downward movement of the holder main body 112 so as to elastically deform the holder wall portions 112a and 112b. That is, the step portions 160 and 170 serves as displacement operating portions. The step portions 160 and 170 include higher portions 161 and 171, lower portions 162 and 172, and taper portions 163 and 173, respectively. The higher portions 161 and 171 differ in height from the lower portions 162 and 172. The taper portions 163 and 173 are provided between the higher portions 161 and 171 and the lower portions 162 and 172. Here, the step portions 160 of the holder wall portions 112a and 112b are referred to as “holder wall step portions 160.” Further, the step portions 170 of the housing 103 are referred to as “housing step portions 170.” In the holder wall step portions 160, the higher portions 161, the taper portions 163, and the lower portions 162 are provided in the stated order from an inlet side of the holder portion 110. In contrast, in the housing step portions 170, the lower portions 172, the taper portions 173, and the higher portions 171 are provided in the stated order from the inlet side of the holder portion 110. The height of the steps and the angle of the tapers of the holder wall step portions 160 are the same or substantially the same as those of the housing step portions 170.

As shown in FIG. 8, when the holder main body 112 is at the top position, the lower portions 172, the taper portions 173, and the higher portions 171 of the housing step portions 170 abut against and interfere with the higher portions 161, the taper portions 163, and the lower portions 162 of the holder wall step portions 160. In other words, this state is a state in which concavities and convexities of the housing step portions 170 and the holder wall step portions 160 are engaged with each other. When movement of the holder main body 112 from the top position to the bottom position is started, due to a taper action between the taper portions 163 of the holder wall step portions 160 and the taper portions 173 of the housing step portions 170, the higher portions 161 of the holder wall step portions 160 climb up the higher portions 171 of the housing step portions 170 (see FIG. 9).

In this manner, the pair of holder wall portions 112a and 112b of the holder main body 112 tilt in a certain amount due to elastic deformation so as to come closer to each other with portions, which are closer to the connection portion 112c, of the pair of holder wall portions 112a and 112b being fulcrums. As a result, the cushion portions 113 and 113 provided in the inner surfaces of the holder wall portions 112a and 112b abut against both surfaces in the thickness direction of the casing 11 of the docking station 10 inserted into the holder portion 110. That is, the casing 11 of the docking station 10 inserted into the holder portion 110 is held by the pair of holder wall portions 112a and 112b from the both sides in the thickness direction.

When the docking station 10 is pulled out of the holder portion 110, due to the force of the elastic members 130, the holder main body 112 is raised from the bottom position to the top position. At the same time, the concavities and convexities of the holder wall step portions 160 of the pair of holder wall portions 112a and 112b and the housing step portions 170 are engaged with each other again.

By the way, the distance between the pair of holder wall portions 112a and 112b of the holder main body 112 is selected on the basis of the thickness of the docking station 10. More specifically, the distance between the holder wall portions 112a and 112b is selected satisfying the following conditions.

1. When the holder portion 110 does not hold the docking station 10, the distance between the holder wall portions 112a and 112b is slightly larger than the thickness of the docking station 10.

2. In order to facilitate insertion of the docking station 10 into the holder portion 110, the distance between the holder wall portions 112a and 112b when the docking station 10 is not held is set to have the maximum value on the inlet side. That is, the distance between the holder wall portions 112a and 112b on the inlet side is larger than on the back side.

3. When the holder portion 110 holds the docking station 10, the cushion portions 113 provided on the inside of the holder wall portions 112a and 112b opposed to each other are set to be capable of pressing the docking station 10 from the both sides in the thickness direction with an appropriate force.

As described above, the stand apparatus 100 according to this embodiment uses the pair of holder wall portions 112a and 112b of the holder main body 112 to press the docking station 10 from the both sides in the thickness direction. In this manner, the stand apparatus 100 according to this embodiment can stably hold the docking station 10 in an upright position. In addition, the stand apparatus 100 according to this embodiment can easily perform the insertion and removal of the docking station 10 by a single operation of an operation of simply inserting the docking station 10 into the holder portion 110 of the stand apparatus 100 from the above and an operation of simply upwardly pulling the docking station 10 out of the holder portion 110.

### [Other Configurations of Holder Main Body 112]

By the way, in the holder main body 112, portions that actually press the casing 11 of the docking station 10 are limited to the areas in which the cushion portions 113 are provided in the entire length thereof in the X-axis direction. In this embodiment, regarding the one side of the holder main body 112, an area of about ⅔ of the entire length thereof in the X-axis direction is used for the portions that actually press the casing 11 of the docking station 10. In the remaining area of ⅓ of the one side of the holder main body 112, communication holes 117 are formed (see FIG. 4 and FIG. 7). The communication holes 117 communicate with certain air holes 12c and 12d of the air holes 12a to 12d formed in the casing 11 of the docking station 10. Those communication holes 117 are arranged in alignment with the positions of the certain air holes 12c and 12d of the air holes 12a to 12d formed in the casing 11 of the docking station 10.

The communication holes 117 are formed in the holder main body 112 of the stand apparatus 100, and hence even if the docking station 10 is mounted on the stand apparatus 100 immediately after the docking station 10 is used, it is possible to prevent heat from being trapped in the casing 11 of the docking station 10 for a long period of time. Thus, it is possible to prevent thermal destruction and the like of function expansion devices in the docking station 10. In particular, for the docking station 10 including the function expansion devices having a large amount of heat generation, such as an optical drive, a hard disk drive, and a GPU, cooling is important.

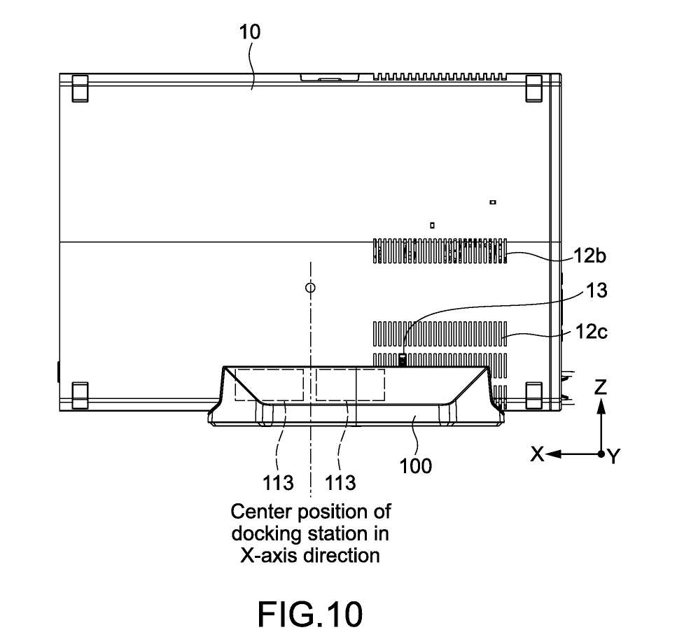

By the way, even when the communication holes 117 as described above are formed in the stand apparatus 100, unless the certain air holes 12c and 12d of the mounted docking station 10 are in alignment with the positions of the communication holes 117 of the holder main body 112, it may be impossible to obtain certain effect. In view of this, in the stand apparatus 100, a positioning portion 118 is provided (see FIG. 4, FIG. 6, and FIG. 7). The positioning portion 118 serves to define a position for mounting the docking station 10 in the X-axis direction. The positioning portion 118 is, more specifically, a protrusion protruding from the inner surface of the one holder wall portion 112b of the holder main body 112. The positioning portion 118 formed of the protrusion is provided to be elongated along the Z-axis direction. On the other hand, the docking station 10 is provided with an engaging portion 13 (see FIG. 3 and FIG. 10) that is engageable to the positioning portion 118 of the stand apparatus 100. More specifically, the engaging portion 13 is an elongated groove. The engaging portion 13 being the elongated groove is formed in the X-Z section of the casing 11 of the docking station 10.

Further, the engaging portion 13 is, as shown in FIG. 3 and FIG. 10, formed in a position deviated from the center of the casing 11 of the docking station 10 in the X-axis direction. With this, the docking station 10 can be prevented from being mounted on the stand apparatus 100 with the right and left being reversed. In addition, the engaging portion 13 is formed only in a portion that will be inserted into the holder portion 110 of the stand apparatus 100. Thus, the docking station 10 can be prevented from being mounted on the stand apparatus 100 with the docking station 10 being upside down. In this manner, it is possible to ensure positional alignment between the air holes 12c and 12d of the mounted docking station 10 and the communication holes 117 of the holder main body 112.

Further, as shown in FIG. 10, in the stand apparatus 100, the docking station 10 is held in such a positional relation that the center of the area of about ⅔ in the X-axis direction, in which the cushion portions 113 are provided in the holder portion 110, corresponds to the center of the docking station 10 in the X-axis direction. With this, the docking station 10 can be stably held.

The weights 120 arranged within the housing 103 serve to prevent the stand apparatus 100 from falling with the docking station 10 being held by the stand apparatus 100 and from being upwardly moved together with the docking station 10 when the docking station 10 is pulled out of the stand apparatus 100. The weights 120 are, for example, formed of metal such as iron or other materials having a high specific gravity. For example, it is desirable that the weights 120 be arranged so that the load of the left weights 120 are equal to the load of the right weights 120, the left weights 120 being opposed to the right weights 120 while interposing the holder portion 110 therebetween.

### MODIFIED EXAMPLE

1. In the housing 103, air communication holes may be provided. With this, it is possible to achieve an increase in cooling efficiency of the docking station 10.

2. Although the positioning portion of the above-mentioned stand apparatus 100 is formed of a protrusion and the engaging portion 13 of the docking station 10 is formed of a groove, in contrast, the positioning portion of the stand apparatus 100 may be formed of a groove and the engaging portion 13 of the docking station 10 may be formed of a protrusion.

3. Although in the above-mentioned stand apparatus 100, the docking station 10 is configured to be held with the sides of the docking station 10 in the Y-axis direction being substantially perpendicular to the stand apparatus 100, the docking station 10 may be configured to be held with the sides of the docking station 10 in the X-axis direction being substantially perpendicular to the stand apparatus 100.

4. In the above-mentioned stand apparatus 100, when the docking station 10 is inserted into the holder portion 110, the pair of holder wall portions 112a and 112b of the holder main body 112 are moved so as to sandwich the docking station 10 therebetween from the both sides in the thickness direction, to thereby hold the docking station 10. However, the present disclosure is not limited thereto. Only the one holder wall portion of the holder main body 112 may be moved so as to sandwich the docking station 10 with respect to the other holder wall portion from the both sides in the thickness direction, to thereby hold the docking station 10.

5. Although in the above-mentioned embodiment, the stand apparatus 100 holds the docking station 10, a target to be held is not limited thereto. The stand apparatus 100 may hold electronic apparatuses such as an optical drive unit and an HDD (Hard Disk Drive) unit.

The present disclosure contains subject matter related to that disclosed in Japanese Priority Patent Application JP 2011-019125 filed in the Japan Patent Office on Jan. 31, 2011, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A stand apparatus comprising:
a holder configured to hold an electronic apparatus so that the electronic apparatus can be inserted into and pulled out of the holder in a direction orthogonal to a thickness direction, the holder including a pair of wall portions capable of holding the inserted electronic apparatus while pressing the inserted electronic apparatus from both sides in the thickness direction;
an elastic member configured to elastically support the holder; and
a displacement operating portion configured to cause the holder to move to a direction opposite to a direction of a repulsion force of the elastic member in response to insertion of the electronic apparatus and to displace at least one of the pair of wall portions to press the electronic apparatus along with the movement.

2. The stand apparatus according to claim 1, wherein
the holder includes a portion configured to hold a part of a casing of the electronic apparatus, the part including an air hole formed therein, and
the portion includes a communication hole capable of communicating to the air hole.

3. The stand apparatus according to claim 2, further comprising a positioning portion configured to engage to the casing of the electronic apparatus that is held by the holder, to thereby position the electronic apparatus in a direction orthogonal to an insertion and pull-out direction and the thickness direction of the electronic apparatus.

4. An electronic apparatus system for a stand apparatus, comprising:
an electronic apparatus including a device configured to expand a function of an information processing apparatus; and
a stand apparatus capable of holding the electronic apparatus, the stand apparatus including
a holder configured to hold the electronic apparatus so that the electronic apparatus can be inserted into and pulled out of the holder in a direction orthogonal to a thickness direction, the holder including a pair of wall portions capable of holding the inserted electronic apparatus while pressing the inserted electronic apparatus from both sides in the thickness direction,
an elastic member configured to elastically support the holder, and
a displacement operating portion configured to cause the holder to move to a direction opposite to a direction of a repulsion force of the elastic member in response to insertion of the electronic apparatus and to displace at least one of the pair of wall portions to press the electronic apparatus along with the movement.
